(19) United States
(12) Patent Application Publication
(10) Pub. No.: US 2011/0024621 A1
(43) Pub. Date: Feb. 3, 2011

(54) SCANNING ELECTRON MICROSCOPE CONTROL DEVICE, CONTROL METHOD, AND PROGRAM

(75) Inventor: Bunshiro SAYA, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 12/826,181

(22) Filed: Jun. 29, 2010

(30) Foreign Application Priority Data
Jul. 29, 2009 (JP) 2009-176679

(51) Int. Cl. H01J 37/28; H01J 37/244

(52) U.S. Cl. 250/307; 250/310

(57) ABSTRACT

An SEM control device comprises: an image acquisition unit that acquires by an SEM a plurality of images of a prescribed object, each of which is formed of a plurality of pixels lined up in a first direction, at a plurality of positions in a second direction perpendicular to the first direction; a variation range calculation unit that obtains maximum values and minimum values of gray scale values among the plurality of images at respective locations of the plurality of pixels, and calculates a variation range of the maximum values and a variation range of the minimum values for the plurality of pixels; and a brightness/contrast adjustment unit that adjusts brightness and contrast of the SEM so as to minimize difference between the variation range of the maximum values and the variation range of the minimum values.

### CROSS-REFERENCE TO RELATED APPLICATION

This application is based upon and claims the benefit of the priority of Japanese patent application No.2009-176679 filed on Jul. 29, 2009, the disclosure of which is incorporated herein in its entirety by reference thereto.

### TECHNICAL FIELD

The present invention relates to a scanning electron microscope (SEM) control device, a control method, and a program, and in particular, to an SEM control device, a control method, and a program that adjusts brightness and contrast of an SEM.

### BACKGROUND

With the miniaturization of semiconductor integrated circuits, length measurement errors of even a few nm are no longer acceptable. A method of performing length measurement based on optical interference is realized in order to reduce length measurement errors. However, objects on which length measurement by optical interference can be carried out are limited to those with simple repeated patterns such as lines and spaces. Therefore, in a case of performing length measurement of a complex pattern when constructing a process, it is necessary to use a scanning electron microscope (SEM).

Length measurement by an SEM, for example, is performed based on an SEM image of 512×512 pixels obtained by performing A/D conversion of secondary electron information obtained when a specimen is scanned by an electron beam, to 0 to 255 gray scale values per pixel.

Patent Document 1 describes an automatic contrast/brightness adjusting device that performs automatic adjustment of detector contrast and image brightness, for a scanned image form obtained by two-dimensionally scanning a charged particle beam, such as an electron beam, an ion beam or the like, on a specimen, to form a scanned image.

[Patent Document 1]

JP Patent Kokai Publication No. JP-P2001-243907A

### SUMMARY

The entire disclosure of Patent Document 1 is incorporated herein by reference thereto. The following analysis was made by the present inventor.

For each SEM device there is an individual difference in a detector that detects secondary electrons, a photomultiplier that amplifies secondary electron information, and the like, so that even in a case where length measurement is performed for an identical place on the specimen, different SEM images are obtained for each device, and length measurement values may be different.

The adjusting device described in Patent Document 1 is an invention related to adjustment of one SEM, and it is not possible to prevent variability of length measurement values among a plurality of SEMs. Furthermore, with the adjusting device described in Patent Document 1, since processing is carried out with data for one frame, the variability between devices regarding length measurement values is large.

Therefore, there is a need in the art to provide an SEM control device, a control method, and a program to prevent variability among devices with regard to length measurement values by an SEM.

According to a first aspect of the present invention, there is provided an SEM (scanning electron microscope) control device comprising:

an image acquisition unit that acquires by an SEM a plurality of images of a prescribed object, each of which is formed of a plurality of pixels lined up in a first direction, at a plurality of positions in a second direction perpendicular to the first direction;
a variation range calculation unit that obtains maximum values and minimum values of gray scale values among the plurality of images at respective locations of the plurality of pixels, and calculates the variation range of the maximum values and the variation range of the minimum values for the plurality of pixels; and
a brightness/contrast adjustment unit that adjusts brightness and contrast of the SEM so as to minimize difference between the variation range of the maximum values and the variation range of the minimum values.

According to a second aspect of the present invention, there is provided an SEM (scanning electron microscope) control method comprising:

acquiring by an SEM a plurality of images of a prescribed object, each of which is formed of a plurality of pixels lined up in a first direction, at a plurality of positions in a second direction perpendicular to the first direction;
obtaining maximum values and minimum values of gray scale values among the plurality of images at respective locations of the plurality of pixels, and calculates a variation range of the maximum values and a variation range of the minimum values for the plurality of pixels; and
adjusting brightness and contrast of the SEM so as to minimize difference between the variation range of the maximum values and the variation range of the minimum values.

According to a third aspect of the present invention, there is provided a program causing a computer to execute:

acquiring a plurality of images of a prescribed object, each of which is formed of a plurality of pixels lined up in a first direction, at a plurality of mutually different positions in a second direction perpendicular to the first direction, by a scanning electron microscope (SEM);
obtaining maximum values and minimum values of gray scale values among the plurality of images at respective locations of the plurality of pixels, and calculating a variation range of the maximum values and a variation range of the minimum values for the plurality of pixels; and
adjusting brightness and contrast of the SEM so that difference between the variation range of the maximum values and the variation range of the minimum values is minimal.

The present invention provides the following advantage, but not restricted thereto. According to the SEM control device, the control method, and the program of the present invention, it is possible to prevent variability between devices with regard to length measurement values by SEM.

### BRIEF DESCRIPTIONS OF THE DRAWINGS

FIG. 1 is a block diagram showing a configuration of an SEM control device according to an exemplary embodiment.

FIG. 2 is a flow chart showing operation of the SEM control device according to an exemplary embodiment.

FIG. 3 is a block diagram showing a hardware configuration of a computer.

FIG. 4 is a drawing showing one example of a plurality of (amount of number of added lines) SEM images obtained by an SEM.

FIG. 5 is a drawing showing gray scale values extracted from the plurality of SEM images shown in FIG. 4.

FIG. 6 is a drawing showing maximum values and minimum values of the gray scale values shown in FIG. 5.

FIG. 7 is a drawing showing difference between the gray scale values shown in FIG. 5 and an average of the gray scale values shown in FIG. 5.

FIG. 8 is a drawing when abnormal values are deleted from the maximum values and minimum values of the gray scale values shown in FIG. 6.

FIG. 9 is a drawing showing difference between variation range of the maximum values and variation range of the minimum values of the gray scale values, with respect to various levels of brightness and contrast.

FIG. 10 is a drawing showing difference between the variation range of the maximum values and the variation range of the minimum values of the gray scale values, with respect to various levels of brightness and contrast, for a plurality of SEMs.

FIG. 11 is a drawing showing difference in length measurement values before and after making brightness and contrast preferable, in each of the SEMs.

### PREFERRED MODES

An SEM control device in a first mode is preferably an SEM control device according to the abovementioned first aspect.

In an SEM control device in a second mode, the variation range calculation unit calculates an average value of gray scale values among a plurality of images at respective locations of a plurality of pixels, and after excluding gray scale values for which the difference from the average value is larger than a prescribed threshold, and obtains maximum values and minimum values of gray scale values.

In an SEM control device in a third mode, an object preferably includes a straight line pattern having an edge parallel to a second direction.

An SEM in a fourth mode preferably has the abovementioned SEM control device.

An SEM control method in a fifth mode is preferably an SEM control method according to the abovementioned second aspect.

In an SEM control method in a sixth mode, the obtaining maximum values and minimum values may comprise calculating an average value of gray scale values among the plurality of images at respective locations of the plurality of pixels, and after excluding gray scale values for which the difference from the average value is larger than a prescribed threshold, obtaining maximum values and minimum values of gray scale values.

A program in a seventh mode is preferably a program according to the abovementioned third aspect.

In a program in an eighth mode, the obtaining maximum values and minimum values may comprise calculating an average value of gray scale values among the plurality of images at respective locations of the plurality of pixels, and after excluding gray scale values for which the difference from the average value is larger than a prescribed threshold, obtaining maximum values and minimum values of gray scale values.

### Exemplary Embodiment

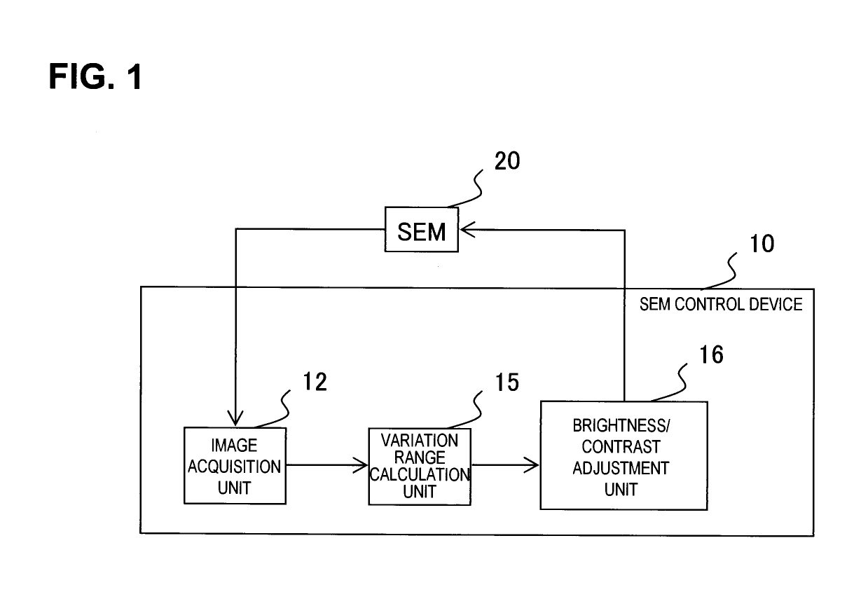

A description is given concerning an SEM control device according to an exemplary embodiment, making reference to the drawings. FIG. 1 is a block diagram showing a configuration of the SEM control device 10 according to the present exemplary embodiment. Referring to FIG. 1, the SEM control device 10 has an image acquisition unit 12, a variation range calculation unit 15, and a brightness/contrast adjustment unit 16.

The image acquisition unit 12 acquires by an SEM (scanning electron microscope) 20 a plurality of images of a prescribed object, each of which is formed of a plurality of pixels lined up in a first direction, at a plurality of positions in a second direction perpendicular to the first direction. The prescribed object preferably includes a straight line pattern (correction pattern, reference pattern) having an edge parallel to the second direction.

The variation range calculation unit 15 obtains maximum values and minimum values of gray scale values among the abovementioned plurality of images, at respective locations of the abovementioned plurality of pixels, and calculates the variation range of the maximum values and the variation range of the minimum values for the abovementioned plurality of pixels.

The brightness/contrast adjustment unit 16 adjusts brightness and contrast of the SEM 20 to minimize (or reduce) the difference between the variation range of the abovementioned maximum values and the variation range of the abovementioned minimum values.

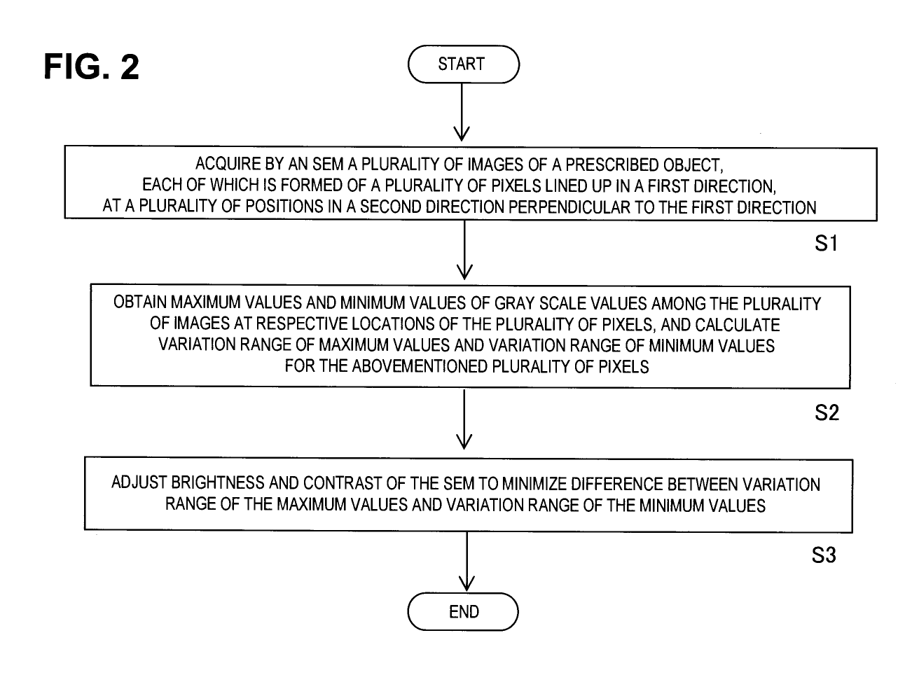

A description is given concerning operation of the SEM control device 10 of the present exemplary embodiment, making reference to the drawings. FIG. 2 is a flowchart showing an operation of the SEM control device 10.

Referring to FIG. 2, the image acquisition unit 12 acquires a plurality of images of the prescribed object, each of which is formed of a plurality of pixels lined up in the first direction, at a plurality of positions in the second direction perpendicular to the first direction, by the SEM (step S1).

The variation range calculation unit 15 obtains maximum values and minimum values of gray scale values among the abovementioned plurality of images, at respective locations of the abovementioned plurality of pixels, and calculates the variation range of the maximum values and the variation range of the minimum values for the abovementioned plurality of pixels (step S2).

The brightness/contrast adjustment unit 16 adjusts brightness and contrast of the SEM to minimize the difference between the variation range of the abovementioned maximum values and the variation range of the abovementioned minimum values (step S3).

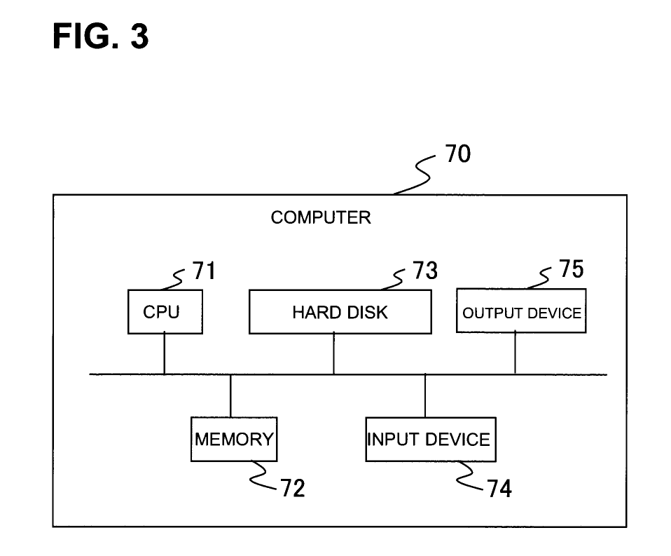

FIG. 3 is a block diagram showing a hardware configuration of a computer, in a case of realizing the SEM control device 10 by the computer. Referring to FIG. 3, the computer 70 has a CPU 71, a memory 72, a hard disk 73, an input device 74, and an output device 75.

Each of these parts may be connected to a bus line. The input device 74 may include a mouse and a keyboard. The output device 75 may have a display. The hard disk 73 may store a program. The CPU 71 executes processing with respect to each part (12, 15, and 16) of the SEM control device 10.

### EXAMPLES

A description is given concerning operation of the SEM control device 10 of the present exemplary embodiment, making reference to the drawings, in a case of using a specific correction pattern.

The image acquisition unit 12, for the correction pattern, acquires an image formed of a plurality of pixels lined up in a first direction, at a plurality of positions in a second direction perpendicular to the first direction, by the SEM (step S1 in FIG. 2). At this time, in order to give consideration to a length measurement error, it is desirable to use a length measurement algorithm identical to when actual length measurement is done.

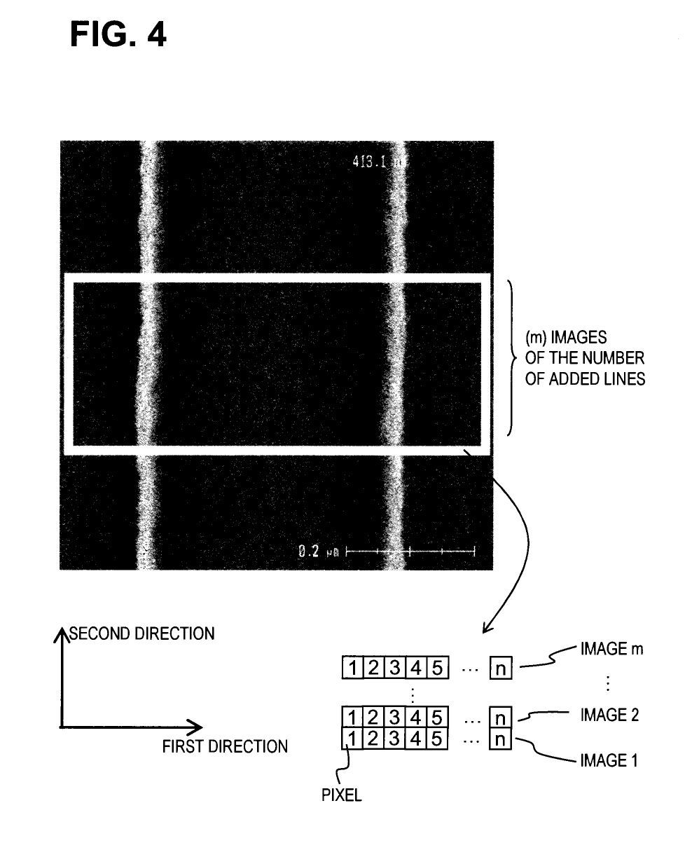

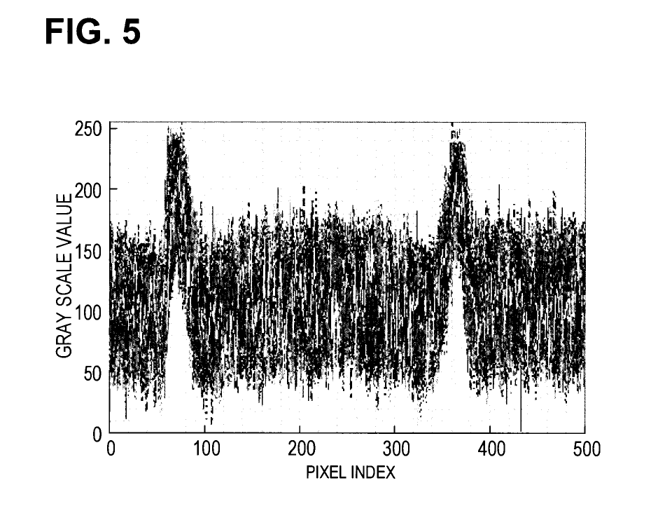

FIG. 4 is a drawing showing an example of a correction line pattern image obtained by the SEM, and an edge of a line pattern shines white (brightly). One image is formed of n (for example, 512) pixels lined up in the first direction. A range shown by a white frame in FIG. 4 is a region of original data for creating FIG. 5, and lines formed of the 512 pixels extend in the first direction, with a sequence of m lines (m pixels, for example, 200) in the second direction.

Next, the variation range calculation unit 15 extracts a gray scale value for each pixel of the abovementioned plurality of images. The variation range calculation unit 15 refers to the length measurement algorithm when an actual length measurement is made, determines the number of added lines, and extracts a gray scale value for this number of added lines. The extracted gray scale values may be graphed, with an X axis as pixel index and a Y axis as gray scale value.

FIG. 5 shows gray scale values extracted from the plurality of SEM images shown in FIG. 4. The horizontal axis corresponds to each of 512 pixels in the first direction shown in FIG. 4, and is represented overlapping gray scale values of m lines (m pixels) in the second direction.

The variation range calculation unit 15 obtains maximum values and minimum values of gray scale values among the abovementioned plurality of images, at respective locations of the abovementioned plurality of pixels (in a first direction of FIG. 4), and calculates the variation range of the maximum values and the variation range of the minimum values for the abovementioned plurality of pixels (step S2 in FIG. 2).

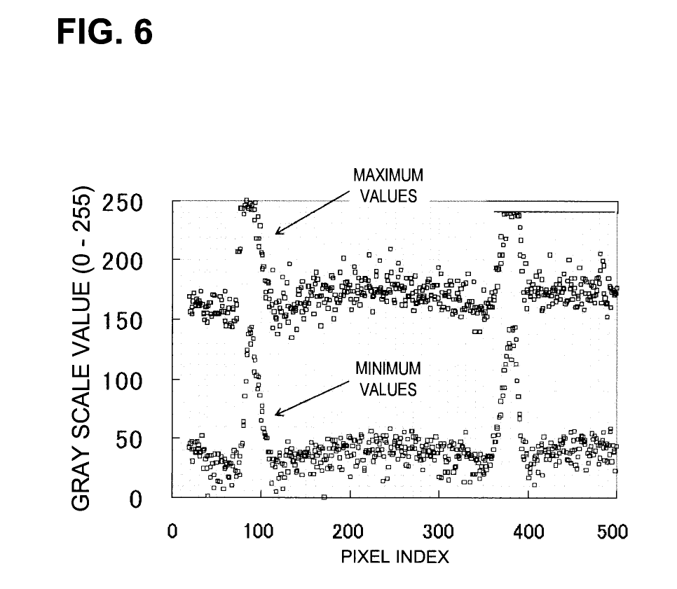

FIG. 6 is a drawing showing maximum values and minimum values of the gray scale values shown in FIG. 5.

Here, the variation range calculation unit 15 may calculate the average value of gray scale values among the plurality of images at respective locations of the plurality of pixels, and after excluding gray scale values for which the difference from the average value is larger than a prescribed threshold, the maximum values and the minimum values of the gray scale values are obtained. For example, in a case where there is a large irregularity at a line pattern edge, or where a portion with a large irregularity is included in a target region, there are many pixels for which difference from the average value is large, but it is possible to inhibit the effect (noise, with regard to an object of the present invention) of variability due to samples by performing this excluding processing, and to extract only information due to SEM state.

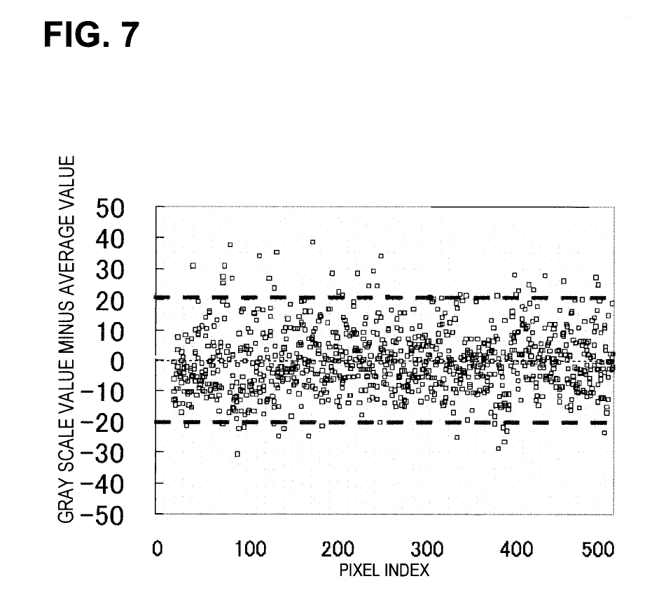

FIG. 7 is a drawing showing difference between the gray scale values shown in FIG. 5 and an average of the gray scale values shown in FIG. 5. In a case where an absolute value of this difference is greater than or equal to a prescribed threshold (for example, 20 in FIG. 5), it is regarded as an abnormal value and is preferably excluded when the maximum values and the minimum values of the gray scale values are extracted. In this way, it is possible to inhibit a noise component in length measurement.

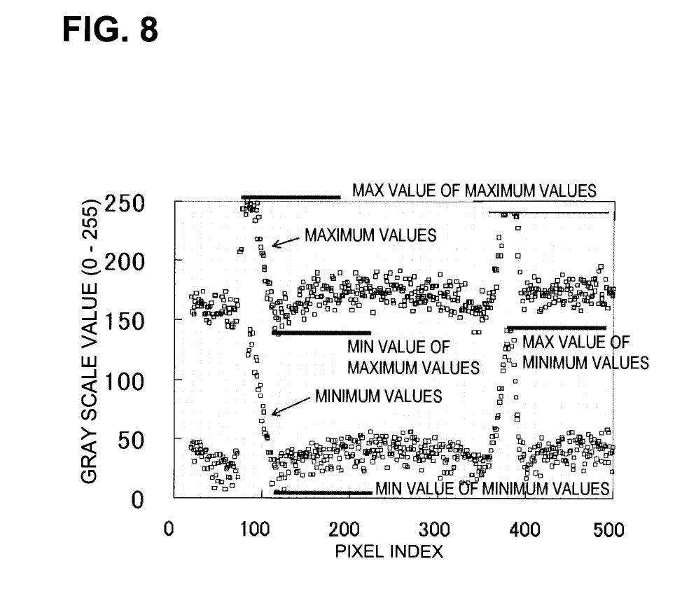

In FIG. 8 abnormal values are deleted from the maximum values and minimum values of the gray scale values shown in FIG. 6.

The brightness/contrast adjustment unit 16 adjusts brightness and contrast of the SEM to minimize the difference between the variation range of the abovementioned maximum values and the variation range of the abovementioned minimum values (step S3 in FIG. 2).

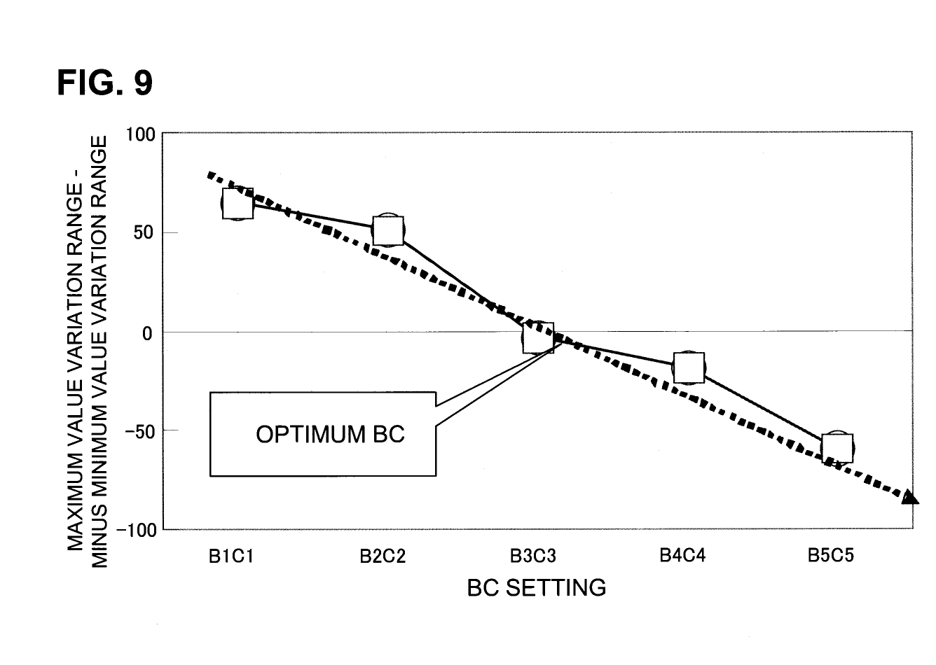

FIG. 9 shows the difference between variation range of the abovementioned maximum values and the variation range of the abovementioned minimum values, with respect to various combinations of brightness and contrast of the SEM. In FIG. 9, “BmCn” indicates that “(brightness, contrast)=(m, n).”

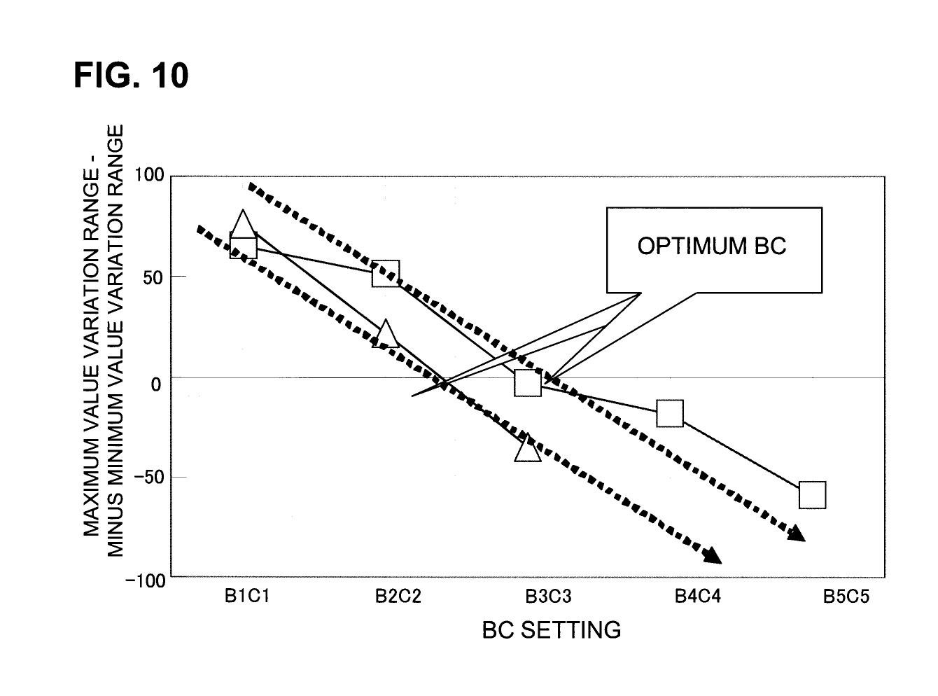

With regard to a plurality of SEMs in which it is desired to inhibit variations in length measurement values, steps S1 to S3 of FIG. 2 are performed. FIG. 10 shows difference between variation range of the maximum values and variation range of the minimum values of the gray scale values, with respect to various levels of brightness and contrast, for a plurality of SEMs.

Referring to FIG. 10, in an SEM A, a combination of preferable brightness and contrast is B2C2, that is, “(brightness, contrast)=(2, 2).” On the other hand, in an SEM B, a combination of preferable brightness and contrast is B3C3, that is “(brightness, contrast)=(3, 3).”q

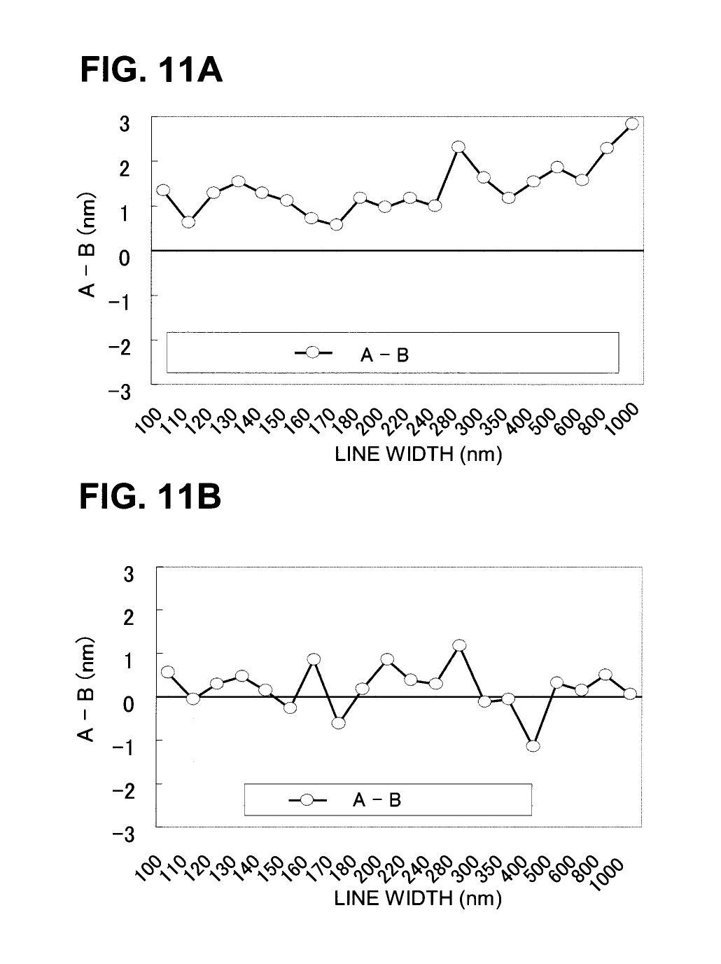

FIG. 11 shows difference in length measurement values (“A-B” in the drawing) before and after making brightness and contrast preferable, in the SEM A and the SEM B. FIG. 11A shows difference in length measurement values between the SEM A and the SEM B, when both the SEM A and the SEM B are B3C3, that is “(brightness, contrast)=(3, 3).” On the other hand, FIG. 11B shows difference in length measurement values between the SEM A and the SEM B, when only brightness and contrast of the SEM A are adjusted to B2C2, that is “(brightness, contrast)=(2, 2).” Referring to FIG. 11B, it is understood that the difference in the length measurement values between the SEM A and the SEM B is small.

In mass production using a conventional method, length measurement is made of size of each element of a semiconductor device (for example, gate length, contact size) using a plurality of SEMs, and containment within a necessary specification range is required. However, in a case where length measurement values that differ greatly according to each SEM device are obtained, it is not possible to manage the size of each element.

On the other hand, according to the SEM control device 10 of the present exemplary embodiment, it is possible to reduce variation between devices for length measurement values by the SEM. By using not one frame but a plurality of frames when an actual length measurement is made, it is possible to reduce error.

The above description has been given based on the examples, but the present invention is not limited to the abovementioned examples. For example, modifications are possible according to needs, such as scale factor of an area to be observed (influencing pixel size), whether or not to extract information of pixels that are sequential in the second direction, usage of an actually used material rather than a standard sample, and the like.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A scanning electron microscope SEM control device comprising:
an image acquisition unit that acquires by an SEM a plurality of images of a prescribed object, each of which is formed of a plurality of pixels lined up in a first direction, at a plurality of positions in a second direction perpendicular to said first direction;
a variation range calculation unit that obtains maximum values and minimum values of gray scale values among said plurality of images at respective locations of said plurality of pixels, and calculates a variation range of said maximum values and a variation range of said minimum values for said plurality of pixels; and
a brightness/contrast adjustment unit that adjusts brightness and contrast of said SEM so as to minimize difference between said variation range of said maximum values and said variation range of said minimum values.

2. The SEM control device according to claim 1, wherein said variation range calculation unit calculates an average value of gray scale values among said plurality of images at respective locations of said plurality of pixels, and after excluding gray scale values for which a difference from said average value is larger than a prescribed threshold, obtains maximum values and minimum values of gray scale values.

3. The SEM control device according to claim 1, wherein said object includes a straight line pattern having an edge parallel to said second direction.

4. The SEM control device according to claim 2, wherein said object includes a straight line pattern having an edge parallel to said second direction.

5. A scanning electron microscope SEM comprising said SEM control device according to claim 1.

6. A scanning electron microscope SEM comprising said SEM control device according to claim 2.

7. A scanning electron microscope SEM comprising said SEM control device according to claim 3.

8. A scanning electron microscope SEM comprising said SEM control device according to claim 4.

9. A scanning election microscope SEM control method comprising:
acquiring by an SEM a plurality of images of a prescribed object, each of which is formed of a plurality of pixels lined up in a first direction, at a plurality of positions in a second direction perpendicular to said first direction;
obtaining maximum values and minimum values of gray scale values among said plurality of images at respective locations of said plurality of pixels, and calculating a variation range of said maximum values and a variation range of said minimum values for said plurality of pixels; and
adjusts brightness and contrast of said SEM so as to minimize difference between said variation range of said maximum values and said variation range of said minimum values.

10. The SEM control method according to claim 9, wherein said obtaining maximum values and minimum values comprises:
calculating an average value of gray scale values among said plurality of images at respective locations of said plurality of pixels; and
after excluding gray scale values for which a difference from said average value is larger than a prescribed threshold, obtaining maximum values and minimum values of gray scale values.

11. A program causing a computer to execute:
acquiring by a scanning electron microscope SEM a plurality of images of a prescribed subject, each of which is formed of a plurality of pixels lined up in a first direction, at a plurality of mutually different positions in a second direction perpendicular to said first direction;
obtaining maximum values and minimum values of gray scale values among said plurality of images at respective locations of said plurality of pixels, and calculating a variation range of said maximum values and a variation range of said minimum values for said plurality of pixels; and
adjusting brightness and contrast of said SEM so as to minimize difference between said variation range of said maximum values and said variation range of said minimum values.

12. The program according to claim 11, wherein said obtaining maximum values and minimum values comprises:
calculating an average value of gray scale values among said plurality of images at respective locations of said plurality of pixels; and
after excluding gray scale values for which said difference from said average value is larger than a prescribed threshold, obtaining maximum values and minimum values of gray scale values.
